(19) United States
(12) Patent Application Publication
(10) Pub. No.: US 2026/0052699 A1
(43) Pub. Date: Feb. 19, 2026

(54) FERROELECTRIC DEVICES WITH METAL OXIDE AND METHODS OF FORMING THEREOF

(71) Applicant: Tokyo Electron Limited, Tokyo (JP)

(72) Inventors: Joshua Mayersky, Albany, NY (US); Sara Otsuki, Albany, NY (US); Dina H. Triyoso, Albany, NY (US)

(21) Appl. No.: 18/807,871

(22) Filed: Aug. 16, 2024

(51) Int. Cl. H10B 53/30; H01L 21/28; H01L 29/51; H01L 29/66; H01L 29/78; H10B 51/10; H10B 51/30; H10B 53/10

(52) U.S. Cl. CPC H10B 53/30; H10B 51/10; H10B 51/30; H10B 53/10; H10D 30/0415; H10D 30/701; H10D 64/033; H10D 64/689

(57) ABSTRACT

A method of forming an electronic device includes forming a first line over a substrate, the first line oriented along a first direction and including a ferroelectric material layer over a first metal electrode; and forming a second line over the first line, the second line oriented along a second direction, the second line including a second metal electrode, a layer of metal oxide, and a layer of metal, the second metal electrode being disposed over the ferroelectric material layer, the layer of metal oxide and the layer of metal being disposed over the second metal electrode, the layer of metal further being disposed along sidewalls of the layer of metal oxide.

### TECHNICAL FIELD

This application relates generally to electronic devices, and, in particular embodiments, to electronic devices incorporating ferroelectric materials and methods for manufacturing and operating the same.

### BACKGROUND

Unlike conventional dielectrics, ferroelectric materials possess a characteristic net electrical polarization—the remanent polarization, Pᵣ—even in the absence of an electric field E. When a sufficiently strong field is applied in opposition to Pᵣ, the polarization state of the ferroelectric switches, and the ferroelectric retains polarization −Pᵣ once the field is removed. As a result, ferroelectric materials fulfill the basic criteria for constructing nonvolatile memory by providing a physical implementation of a bit (two distinct polarization states) that does not require refreshing.

Because ferroelectrics also typically have high dielectric constants (low capacitance equivalent thicknesses, CETs), they are attractive materials for the design and fabrication of compact, low-power devices. Replacing conventional dielectrics with ferroelectrics yields ferroelectric random-access memory (FeRAM), ferroelectric tunnel junctions (FTJs), and ferroelectric field-effect transistors (FeFETs), among other conceivable devices. Ferroelectrics may not only serve as a drop-in replacement for conventional dielectrics, but their unique electrical properties may substantially improve the performance of some devices. For example, FTJs have giant tunneling resistances modulated by the ferroelectric polarization state, with OFF/ON resistance ratios as high as 10⁴.

The principal barrier to wider adoption of ferroelectric devices in commercial products, and specifically for memory devices, is an asymmetry in their read-write properties: Ferroelectric memories have nearly unlimited durability to read operations, but they exhibit relatively rapid fatigue and eventual breakdown when written. Fatigue in ferroelectrics is characterized by incremental reductions in the magnitude of Pᵣ that eventually compromise the distinguishability of the polarization states and lead to soft errors. In some instances, fatigue may measurably affect device properties (such as threshold voltages in a FeFET) within as few as 10³ read-write cycles. As such, there is significant interest in improving the durability of ferroelectric devices.

### SUMMARY

A method of forming an electronic device includes forming a first line over a substrate, the first line oriented along a first direction and including a ferroelectric material layer over a first metal electrode; and forming a second line over the first line, the second line oriented along a second direction, the second line including a second metal electrode, a layer of metal oxide, and a layer of metal, the second metal electrode being disposed over the ferroelectric material layer, the layer of metal oxide and the layer of metal being disposed over the second metal electrode, the layer of metal further being disposed along sidewalls of the layer of metal oxide.

An electronic device includes a first metal electrode including a first metal; a second metal electrode including a second metal and disposed over the first metal electrode; a ferroelectric material layer disposed between the first metal electrode and the second metal electrode; a layer of metal oxide disposed over the ferroelectric material layer; and a layer of metal disposed over the second metal electrode, the layer of metal further being disposed along sidewalls of the layer of metal oxide.

A method of operating an electronic device includes having the electronic device including a first metal electrode including a first metal; a second metal electrode including a second metal and disposed over the first metal electrode; a ferroelectric material layer disposed between the first metal electrode and the second metal electrode, the ferroelectric material layer including a third metal; a layer of metal oxide disposed over the second metal electrode, the layer of metal oxide including a fourth metal; and a first layer of metal disposed over the second metal electrode, the first layer of metal further being disposed along sidewalls of the layer of metal oxide; and applying a plurality of switching cycles between the first metal electrode and the second metal electrode to switch a state of the ferroelectric material layer, the applying supplying oxygen from the layer of metal oxide to the ferroelectric material layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B present cross-sectional and top-down views of an electronic device comprising a ferroelectric capacitor disposed beneath a layer of metal oxide, in accordance with various embodiments;

FIG. 2 provides a table of Gibbs energies of the oxygen-supplying reactions between various metal oxides and both hafnium and zirconium, along with conduction properties for the corresponding base metals of the oxides;

FIG. 3 is a chart of the Gibbs energies tabulated in FIG. 2 for reactions with hafnium and products of the electron mean free path and bulk resistivity for the corresponding base metals of the oxides;

FIG. 4 is a flow chart for a method of forming an electronic device, and in particular for forming a ferroelectric capacitor disposed beneath a layer of metal oxide, in accordance with embodiments;

FIGS. 5A-5P illustrate cross-sectional views of the formation of a ferroelectric capacitor disposed beneath a layer of metal oxide, followed by formation of a contact via to an electrode of the capacitor, in accordance with various embodiments;

FIGS. 6A-6P provide complementary top-down views of the formation of a ferroelectric capacitor disposed beneath a layer of metal oxide, followed by formation of a contact via to an electrode of the capacitor, in accordance with various embodiments;

FIGS. 7A and 7B present cross-sectional and top-down views of an electronic device comprising a ferroelectric capacitor with a layer of metal oxide adjacent to a ferroelectric material layer and surrounded by a metal electrode, in accordance with various embodiments; and

FIG. 8 is a flow chart for a method of operating an electronic device, and in particular for operating electronic devices of the types depicted in FIGS. 1A/1B and FIGS. 7A/7B as well as other embodiment devices, in accordance with various embodiments.

### DETAILED DESCRIPTION OF ILLUSTRATIVE EMBODIMENTS

Pristine ferroelectric materials often have a small remanent polarization that grows over repeated read-write cycling, a phenomenon called “wake-up.” With continued use, Pᵣ may reach a peak and then begin to decrease again, signaling the onset of fatigue. Fatigue eventually comes to an end when the device breaks down entirely.

Wake-up, fatigue, and breakdown stem from the same microscopic origin, namely, a field-modulated aging or ripening of the structure of the ferroelectric. These phenomena may be explained with reference to a specific ferroelectric material, such as hafnium zirconium oxide (HZO).

HZO materials have a continuum of possible formulas HfₓZr₁₋ₓO₂ (0≤x≤1), with HfO₂ (hafnia, x=1) and other hafnium-rich compositions being conventional dielectrics; compositions with x≈0.5 (i.e., near-equal amounts of hafnium and zirconium) being ferroelectric; and zirconium-rich compositions and ZrO₂ (zirconia, x=0) being antiferroelectric, with a vanishing polarization at zero field. The properties of HZO may be tuned both by the choice of x and by doping with metals (such as aluminum, silicon, yttrium, or lanthanum) or non-metals (such as hydrogen, carbon, or nitrogen).

Ferroelectricity and antiferroelectricity in these latter HZO compositions originate in a bistability of their crystal structures. Two different arrangements of oxygens relative to the metal atoms are energetically equivalent in the absence of an electric field. When a field is applied, however, partial charges on each atom interact with the electric field to break this energetic symmetry, and one or the other arrangement (and the corresponding sign of a local dipole) will be preferred. In ferroelectric materials, regions known as domains form where local electrical dipoles align in the same direction, resulting in a significant overall polarization of the material. Conversely, in antiferroelectric materials, the local electrical dipoles tend to alternate in direction from one region to the next. This alternating pattern leads to a negligible overall polarization of the material. Despite this lack of net polarization, antiferroelectric materials still maintain a high dielectric constant.

Even when prepared with careful attention to composition, HZO films typically comprise a mixture of grains corresponding to three distinct phases: an antiferroelectric tetragonal (t) phase, a ferroelectric orthorhombic (o) phase, and a paraelectric monoclinic (m) phase. (Paraelectric materials have nonlinear polarization behavior when a field is applied but no remanent polarization and no microscopic ordering of local dipoles, and thus are of no use for memory.) The t- and o-phases interconvert relatively freely, with the o-phase being slightly preferred for grains of larger size. Both t- and o-phases are significantly less stable than the m-phase as grains grow, but a large activation barrier tends to suppress interconversion—at least, as long as energy is not introduced into the system in the form of elevated temperatures or fields. In other words, read-write cycles provide energy that facilitates conversion of the t-phase to the o-phase and (ultimately) to the m-phase, degrading the ferroelectric properties of the HZO material.

HZO films may be deposited and annealed over (or while capped by) an electrode material with an incommensurate structure (e.g., lattice mismatched or misaligned), such as tungsten or titanium nitride, which generates a strain favoring the formation of grains of the t- and o-phases. With repeated read-write cycling, the (initially relatively small) grains may fuse, and larger grains of the t-phase may convert to the o-phase. Both processes tend to make a film more uniformly ferroelectric and to increase the remanent polarization. While some grains of the o-phase may also convert irrecoverably to the paraelectric m-phase, there will be a net improvement in device properties during this wake-up period.

As cycling continues, the t-phase may be exhausted, and o-phase grains may further convert to the m-phase. At some point, the net effect of these processes will be to reduce the remanent polarization irreversibly, if only little by little. This fatigue period continues until the device breaks down.

In addition to varying numbers and sizes of t-, o-, and m-phase grains, an HZO film may also initially have a deposition process-determined concentration of defects, particularly oxygen vacancies with a +2 charge (V_{O}²⁺). The presence of these vacancies encourages the formation of t-phase grains when HZO films are deposited, extending the wake-up period. For this reason, and in accordance with various embodiments, HZO films may be deposited by a process such as atomic layer deposition (ALD) with a timed dose of an oxidant, such as water, which tends to increase the concentration of vacancies.

Over many read-write cycles, however, oxygen vacancies are believed to be the cause of breakdown. Like other types of defect, V_{O}²⁺ accumulates at grain boundaries within a film and at its surface. As the film ages and grains of the stable m-phase grow, V_{O}²⁺ may form a continuous path from one surface of the film to the other along m-phase grain boundaries, forming a leakage path that shorts the device.

Embodiments enable the production of ferroelectric devices with a better write endurance by supplying oxygen to fill vacancies in the working ferroelectric. Filling vacancies continually may enable greater use of oxidants when depositing ferroelectrics, increasing the relative proportion of t-phase grains and extending the wake-up period, while also forestalling device breakdown by preventing the formation of leakage paths.

Oxygen cannot be safely or practicably supplied from an external source (such as a gas cylinder) to all of the ferroelectric components packaged within a finished chip. Rather, in various embodiments, reservoirs of oxygen—in the form of oxygen-containing materials—may be disposed adjacent (or in proximity to) the ferroelectric material layers and configured to supply oxygen to them as needed.

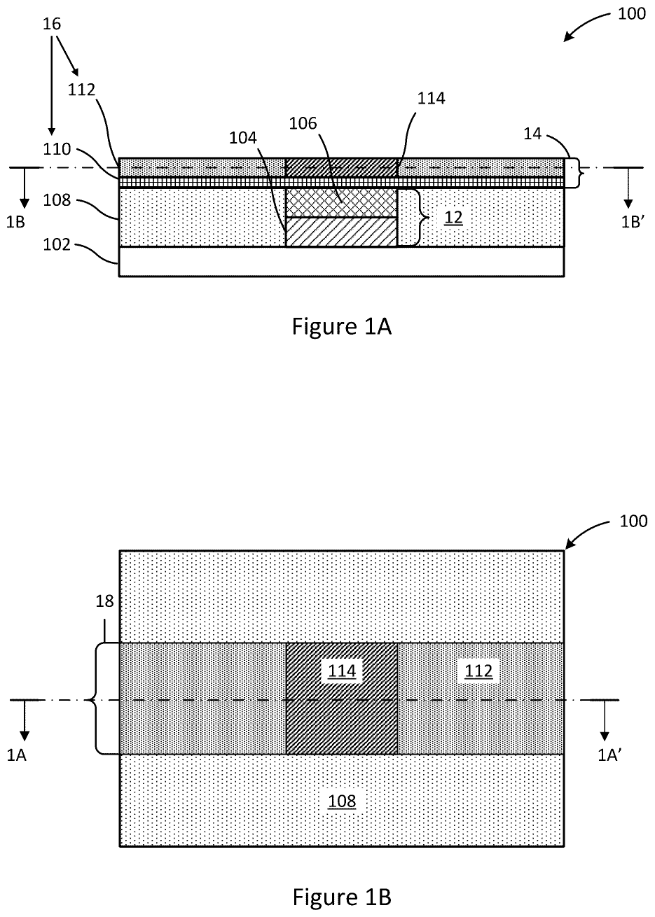

FIGS. 1A-1B illustrate an electronic device including a ferroelectric capacitor with a layer of metal oxide in accordance with embodiments, wherein FIG. 1A illustrates a cross-sectional view and FIG. 1B illustrates a top sectional view. In particular, FIG. 1A depicts a cross-sectional view along a line 1A-1A′ indicated in FIG. 1B, while FIG. 1B illustrates a top sectional view indicated in FIG. 1A by a line 1B-1B′.

Advantageously, and as discussed in further detail below, an oxygen reservoir in the form of a layer of metal oxide 114 is placed in proximity to a ferroelectric material layer 106 without actually being incorporated into the device stack. Because of this separation, improvements to the durability of existing FeRAM, FTJ, and FeFET devices may be achieved without entailing a lengthy redesign process to account for changes in CETs and other design specifications.

Referring now to FIGS. 1A and 1B, a first metal electrode 104 (or bottom electrode) is disposed over a substrate 102. The substrate 102 may be a bulk substrate such as a blank silicon wafer, a silicon-on-insulator (SOI) wafer, or any of various other semiconductor substrates. The substrate 102 may also be coated or layered with any number of additional materials, including compound semiconductors, metal or metalloid oxides, or metal or metalloid nitrides. The substrate 102 may include any material portion or structure of a device, particularly a semiconductor or other electronics device. Similarly, in some embodiments, the substrate 102 may itself be patterned or embedded in other components of a semiconductor structure or device, such as a reconstituted wafer in a wafer level package process.

The first metal electrode 104 may comprise any suitable conductive material, including metals such as cobalt, nickel, copper, platinum, iridium, ruthenium, or tungsten; conductive nitrides such as titanium nitride or tantalum nitride; or conductive oxides such as iridium (IV) oxide, ruthenium (IV) oxide, lanthanum strontium cobalt oxide (LSCO), strontium ruthenium oxide (SRO), or lanthanum-doped SRO, according to various embodiments.

With further reference to FIGS. 1A and 1B, a ferroelectric material layer 106 is disposed between the first metal electrode 104 and a second metal electrode 110 (or top electrode) of the electronic device 100. The second metal electrode 110 may comprise any suitable conductive material, such as those enumerated for the first metal electrode 104. More generally, the first metal electrode 104 and the second metal electrode 110 may respectively comprise a first metal and a second metal. In some embodiments, the second metal may comprise the first metal or be identical to it; in certain of these latter embodiments, the second metal electrode 110 may have the same overall composition as the first metal electrode 104.

With respect to the ferroelectric material layer 106, in some embodiments it may comprise hafnium zirconium oxide (HZO), with or without doping (as described above). In other embodiments, the ferroelectric material layer 106 may comprise hafnium oxide (hafnia, HfO₂) with or without dopants such as aluminum, silicon, or other possibilities described above. With reference to HZO. In still other embodiments, the ferroelectric material layer 106 may comprise a perovskite, such as lithium niobate, barium titanate, bismuth ferrite, lead zirconate titanate (PZT), or lead magnesium niobate-lead titanate (PMN-PT); a layered perovskite such as strontium bismuth tantalate; a wurtzite, such as zinc magnesium oxide; or another ferroelectric compound, such as indium (III) selenide. More generally, the ferroelectric material layer may comprise a third metal.

During the initial deposition and annealing steps, a thicker second metal electrode 110 may help to facilitate proper crystallization of the ferroelectric material layer. The second metal electrode 110 may provide the necessary stress conditions for the hafnium zirconium oxide (HZO) to crystallize into its desired ferroelectric phase. However, once crystallization is achieved, as will be described in various embodiments, the second metal electrode 110 may be thinned down locally to enable oxygen diffusion between the ferroelectric material layer 106 and the layer of metal oxide 114 (serving as an oxygen-supplying layer, OSL). In embodiments, the second metal electrode 110 may be thin enough to allow oxygen to diffuse from the OSL (layer of metal oxide 114) to the ferroelectric material layer 106, filling oxygen vacancies and improving device performance over time. Simultaneously, it may be thick enough to maintain its role as an effective electrode and to preserve the crystalline structure of the underlying ferroelectric material. In various embodiments, the second metal electrode 110 in thinned regions (below the layer of metal oxide 114) may be within a range of 1 nm to 20 nm, e.g., 2 nm to 10 nm in another embodiment.

A layer of metal 112 and a layer of metal oxide 114 are disposed over the second metal electrode 110, with the layer of metal 112 further being disposed along sidewalls of the layer of metal oxide 114. (In other words, the layer of metal 112 is non-contiguous and flanks the layer of metal oxide 114.) According to various embodiments, the layer of metal 112 may comprise any suitable conductive material, such as those described for the first metal electrode 104 and the second metal electrode 110. In one class of embodiments, the second metal electrode 110 and the layer of metal 112 may be made of the same material; in one subset of embodiments in this class, the first metal electrode 104 may further be made of the same material.

The second metal electrode 110 and the layer of metal 112 may be considered components of a composite electrode 16. In some embodiments, these components may have identical compositions and may not be separated by an obvious boundary, for example, if formed by distinct atomic layer deposition steps using identical precursors and under matching process conditions. In other embodiments fabricated by other means—even those in which the second metal electrode 110 and the layer of metal 112 may have identical compositions—a boundary may be present between these components of the electronic device 100, as illustrated in FIG. 1A.

The layer of metal oxide 114 comprises a metal oxide that is configured to supply oxygen to the ferroelectric material layer 106, according to a thermodynamic heuristic described in detail below. The second metal electrode 110 may accordingly comprise a thickness between 1 nm and 20 nm, e.g., 2 nm to 10 nm in one embodiment, such that the second metal electrode 110 serves as a thin barrier both to oxygen provision and (advantageously) to oxygen loss from the ferroelectric material layer 106.

The layer of metal oxide 114 may comprise a main-group metal or a transition metal. In some embodiments, the layer of metal oxide may comprise a binary compound of a transition metal and oxygen (i.e., a compound with chemical formula MₓO_{y} for arbitrary values of the subscripts x and y). In other embodiments, the layer of metal oxide 114 may comprise a transition metal with a +2 oxidation number, such that a corresponding compound may be an oxide MO, a mixed oxide such as M₃O₄ (not excluding other mixed stoichiometries), a peroxide M(II)O₂, a superoxide M(II)(O₂)₂, or an ozonide M(II)(O₃)₂. In certain embodiments, the metal oxide may comprise a transition metal such as silver, copper, ruthenium, tantalum, titanium, molybdenum, tungsten, vanadium, manganese, cobalt, nickel, zinc, niobium, or tin. In still other embodiments, the metal oxide layer may comprise ternary (M^{(a)}ₓM^{(b)}_{y}O_{z}), quaternary (M^{(a)}ₓM^{(b)}_{y}M^{(c)}_{z}O_{w}), or higher metal oxides of a set of metals {M^{(a)}, M^{(b)}, M^{(c)}, . . . }.

The layer of metal oxide 114 may (more generally) comprise a fourth metal. According to various embodiments, the fourth metal may comprise a lower affinity for oxygen than the third metal of the ferroelectric material layer 106. The relative affinities of the third metal and fourth metal for oxygen may be assessed according to any suitable thermodynamic heuristic, such as those described below.

The placement of the oxygen-supplying layer (layer of metal oxide 114) above the second metal electrode 110, rather than in direct contact with the ferroelectric material layer 106, offers several advantages in device design and performance. This configuration allows for better control of the device's electrical properties while still providing the benefits of oxygen vacancy filling. By having the second metal electrode 110 serve as a thin barrier between the ferroelectric material layer 106 and the OSL (layer of metal oxide 114), the device maintains a well-defined metal-insulator-metal (MIM) structure. This device structure may help to preserve the desired electrical characteristics of a ferroelectric capacitor, such as its coercive voltage and remanent polarization. Maintaining physical contact between the second metal electrode 110 and the ferroelectric material layer 106 may also allow for better matching of Fermi levels, which can reduce leakage current flowing through the device. Additionally, this arrangement permits the use of established annealing processes for crystallizing the ferroelectric material layer 106 using the second metal electrode 110 as a capping layer, which may provide the necessary stress conditions for proper crystallization. The OSL (layer of metal oxide 114), positioned above this structure, can still fulfill its role of providing oxygen to fill vacancies in the ferroelectric material layer 106 over time, as oxygen can diffuse through the (thin) second metal electrode 110. This gradual process of oxygen migration can lead to improved performance and endurance over the device lifetime, without compromising the initial electrical properties of the ferroelectric capacitor.

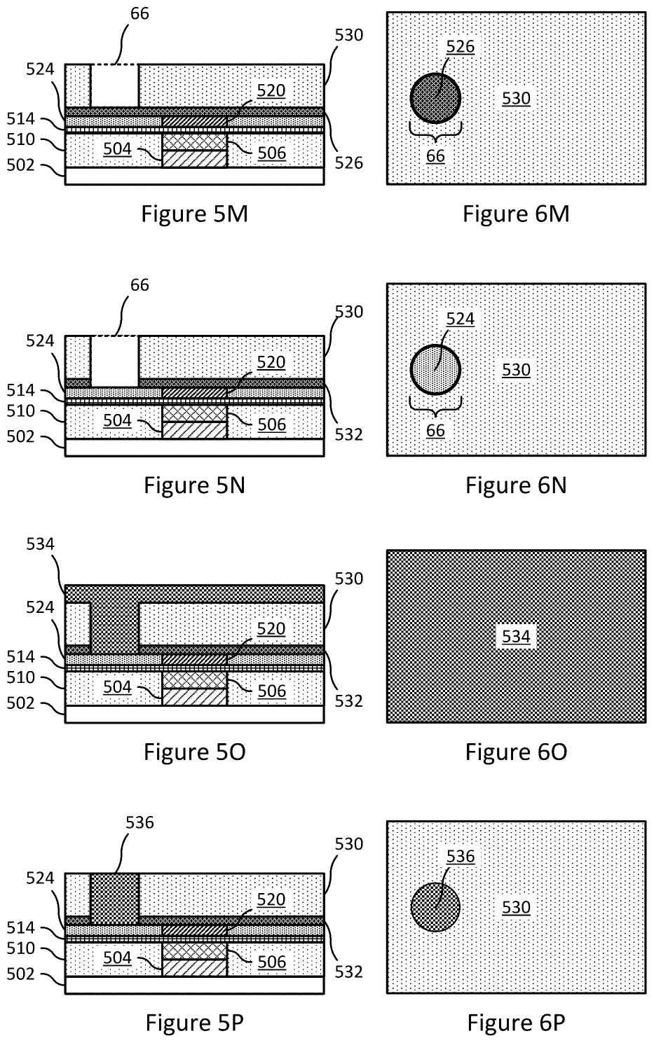

In various embodiments, such as those just described, the layer of metal oxide 114 is disposed over the ferroelectric material layer 106 with the second metal electrode 110 in between, such that the layer of metal oxide 114 is also disposed over the second metal electrode 110. In various embodiments to be described in further detail below with references to FIGS. 7A and 7B, the layer of metal oxide 114 may be disposed over the ferroelectric material layer 106 without being disposed in its entirety over the second metal electrode 110.

Considered at a higher level of structural abstraction, and with further reference to FIGS. 1A and 1B, the electronic device 100 comprises a first line 12 disposed over the substrate 102 and a second line 14 disposed over the first line 12. The first line 12 comprises the first metal electrode 104 and the ferroelectric material layer 106, while the second line 14 comprises the second metal electrode 110, the (non-contiguous) layer of metal 112, and the layer of metal oxide 114.

The second line 14 may be oriented at any angle relative to the first line 12 within a range from 0° (collinear geometry) to 90° (orthogonal or crosspoint geometry, as illustrated in FIGS. 1A and 1B), according to a continuum of embodiments. In embodiments with non-collinear geometry, the second line 14 is disposed within a trench 18 in an interlayer dielectric 108 that flanks the first line 12 and further covers portions thereof. The interlayer dielectric 108 may comprise silicon oxide, silicon nitride, silicon oxynitride, or another high-k dielectric material, in some embodiments. In other embodiments, the interlayer dielectric 108 may comprise a low-k dielectric material such as organo- or fluorosilicate glass, a porous dielectric such as black diamond (BD1, BD2, or BD3 forms of SiOC:H), or a polymer dielectric.

In some embodiments with collinear geometry, the interlayer dielectric 108 may flank the first line 12 and the second line 14, which are stacked, such that an upper surface of the interlayer dielectric 108 is flush with an upper surface of the layer of metal oxide 114. In other collinear embodiments, the interlayer dielectric 108 may be absent. Similarly, in some collinear embodiments, the layer of metal 112 may be absent, or the layer of metal 112 and the layer of metal oxide 114 may alternate along the length of the device. In still other collinear embodiments, the layer of metal 112 may be absent altogether.

The advantageous properties of the electronic device 100 arise in part from a judicious choice of the layer of metal oxide 114, which may be configured to supply oxygen to the ferroelectric material layer 106 through the thin barrier established by the second metal electrode 110, filling oxygen vacancies V_{O}²⁺ and endowing the electronic device 100 with greater durability. (Oxygen-supplying reactions may have a similar effect on ferroelectrics comprising a metal and a chalcogen, such as indium (III) selenide.) That oxygen-supplying process comprises many individual reactions between molecules of the layer of metal oxide 114 and oxygen-deficient metal atoms of the ferroelectric material layer 106. The details of each reaction may be of fundamental interest, but in various embodiments, and in practice, all that may be desired is a reasonable heuristic for selecting oxygen-containing materials to pair with a given ferroelectric.

Filling one or more oxygen vacancies may be understood as an oxidation-reduction (redox) reaction between a metal in the ferroelectric and an oxygen-supplying partner. A generic example of such a redox reaction is the formation of a binary metal oxide from the bare metal and elemental oxygen:

$$mM ( s ) + \frac{n}{2} {O}_{2} ( g ) \to {M}_{m} {O}_{n} ( s ) \qquad ( Equation 1 )$$

Assuming that the oxide in question does not contain superoxide, peroxide, or ozonide anions—though they may be accounted for if need be—the metal (initially with oxidation number, or ON, 0) reacts with oxygen gas (also ON 0) to yield a metal oxide (the metal within the oxide having ON+2n/m, relatively oxidized). The corresponding oxidation half-reaction is simply

$$M \to {M}^{+ 2 n / m} + \frac{2 n}{m} {e}^{-} \qquad ( Equation 2 )$$

Consequently, the thermodynamics of reactions in the form of Equation 1 may be used to assess the relative affinities of different metals for oxygen. The standard electrode potentials of half-reactions in the form of Equation 2 (albeit reversed, according to convention) may be used to assess the relative tendencies of different metals to be oxidized (or reduced). In various embodiments, such assessments (by pairwise comparison, ranking, or some other method) may form the basis for a heuristic choice of oxygen-containing material to supply oxygen to the ferroelectric. In other embodiments, additional mechanistic and kinetic factors may be considered; in still other embodiments, thermodynamics, kinetics, and mechanism may be used to provide a rigorous, global assessment of the oxygen-supplying capabilities of a given oxide when paired with a ferroelectric of interest.

For the thermodynamic heuristic based on Equation 1, and in various embodiments, it may be convenient to use the corresponding Gibbs energy of formation, ΔG_{f}, which is negative for spontaneous reactions. Gibbs energies are typically tabulated for compounds in their standard states, typically at 1 bar pressure and at 25° C., and reported in kcal/mol or kJ/mol; such values are denoted with a plimsoll symbol or degree symbol in the superscript, ΔG_{f}^{o} or ΔG_{f}^{o}. Because Gibbs energies, enthalpies, and entropies are state functions, these quantities may be combined for known reactions to obtain the corresponding values for reactions of interest not otherwise tabulated, in accordance with Hess's laws for thermochemistry.

The Gibbs energy has form ΔG_{f}=ΔH_{f}−TΔS_{f}, where ΔHf is the enthalpy of formation, ΔS_{f}, is the entropy of formation, and T is the absolute temperature in K. Because Equation 1 involves a net loss of gas, ΔS_{f} will generally be negative, and the entropic contribution—TΔS_{f} will generally be positive. Accordingly, the spontaneity of the reaction will be determined in the first instance by the enthalpy, with negative enthalpies being required for spontaneity. Even assuming a negative enthalpy, the entropic contribution may become important at higher temperatures, with the reaction no longer being spontaneous above T_{eq}=(ΔH_{f}/ΔS_{f}). Therefore, in other embodiments, and especially at lower temperatures, the thermodynamic heuristic may instead be based on the enthalpy of formation.

An oxide OxA (properly M^{A}ₖ [symbol] , with corresponding base metal M^{A}) will tend to transfer oxygen to a bare metal M^{B} (with corresponding oxide OxB, or M^{B}ₘOₙ) if it has a less negative Gibbs energy, ΔG_{f}(OxA)>ΔG_{f}(OxB). The greater the difference between the two Gibbs energies, the greater the thermodynamic driving force will be for OxA to make the transfer. Analogous reasoning applies when comparing enthalpies, and also when comparing the standard electrode potentials E^{o} (in volts) appropriate for use with Equation 2.

Standard electrode potentials are tabulated for individual atoms undergoing reduction, and thus directly provide information about the tendency of any given single atom with a certain ON to be reduced. By contrast, the Gibbs energies and enthalpies reflect the thermodynamics of forming oxide molecules that may comprise multiple atoms of one or more metals. That being the case, an additional thermodynamic heuristic may be obtained by normalizing the Gibbs energies or enthalpies of formation by the oxides' respective total numbers of metal atoms. For example, an oxide OxA comprising 3 metal atoms may have a Gibbs energy per metal atom ΔG̅_{f}(OxA)=(ΔG_{f}(OxA)/3). Comparing ΔG̅_{f}(OxA) with ΔG̅_{f}(OxB) indicates the relative affinity of an average metal atom in each oxide for oxygen; as before, OxA will tend to transfer oxygen to an average bare metal atom of OxB when ΔG̅_{f}(OxA)>ΔG̅_{f}(OxB).

A more quantitative thermodynamic heuristic tailored to a given choice of ferroelectric oxide may be developed based on a balanced equation for the oxygen-supplying reaction between OxA and M^{B}, namely

$$n {M}^{{A}_{k}} {O}_{ℓ} ( s ) + ℓ m {M}^{B} ( s ) \to kn {M}^{A} ( s ) + ℓ {M}_{m}^{B} {O}_{n} ( s ) . \qquad ( Equation 3 )$$

The corresponding Gibbs energy of reaction is given by

$$Δ {G}_{rxn} = ℓΔ {G}_{f}^{°} ( OxB ) - n Δ {G}_{f}^{°} ( OxA ) , \qquad ( Equation 4 )$$

up to any common integer factors that may exist for the stoichiometric coefficients in Equation 3, which should be divided out.

As with the Gibbs energy of formation, a normalized version of ΔGᵣₓₙ indicating the relative propensity of OxA to transfer oxygen to an individual metal atom M^{B} of OxB may be obtained by dividing out an additional factor of m. The resulting ΔG̅ᵣₓₙ may be another acceptable thermodynamic heuristic. Irrespective of normalization, larger negative values of ΔGᵣₓₙ may indicate a stronger thermodynamic driving force for supply of oxygen from a layer of metal oxide 114 comprising OxA to a ferroelectric material layer 106 comprising metal atom M^{B}, according to various embodiments.

Similar balanced equations may be written to obtain the Gibbs energies of oxygen-supplying reactions involving ternary, quaternary, and higher metal oxides. In these cases, the Gibbs energy per average metal atom may be obtained by dividing ΔGᵣₓₙ by the total number of metal atoms in OxB. In such embodiments, larger negative values of the corresponding Gibbs energy of reaction may again indicate a stronger thermodynamic driving force for the corresponding oxygen-supplying process. Similarly, and with modest modifications to account for compositional differences, the thermodynamic driving force for filling oxygen vacancies with sulfur, selenium, or tellurium from metal chalcogenides may be assessed.

A complementary criterion for choosing a metal oxide arises from considering the effect of oxygen-supplying reactions like Equation 3. Each time that a molecule of the layer of metal oxide 114 supplies oxygen to the ferroelectric material layer 106, an oxygen vacancy (and thus an oxygen-deficient or bare metal atom) may be formed in the layer of metal oxide 114. Such vacancies may at first be refilled by oxygen from portions of the layer of metal oxide disposed farther from the second metal electrode 110 (and thus farther from the ferroelectric material layer 106). Eventually, enough oxygen may be supplied from the layer of metal oxide 114 to the ferroelectric material layer 106 that the resulting vacancies may not be refilled so readily. At such time, the interface between the layer of metal oxide 114 and the second metal electrode 110 may begin to accumulate vacancies, eventually comprising a substantial portion of bare atoms of the fourth metal. (Recall, with reference to FIGS. 1A and 1B, that the first metal electrode 104, second metal electrode 110, ferroelectric material layer 106, and layer of metal oxide respectively comprise first, second, third, and fourth metals.) This aging or ripening of the layer of metal oxide 114 may therefore affect the electrical properties of the second line 14 by contributing an additional metallic component to the composite electrode 16, namely, a second layer of metal comprising the fourth metal.

Thus, in some embodiments, an electrical criterion for choosing the layer of metal oxide 114 may be considered as well, given a suitable electrical metric. For example, the electrical metric may be the mean free path λ for electron-phonon scattering in the corresponding fourth metal. In other embodiments, the electrical metric may be the bulk resistivity po of the corresponding fourth metal. In still other embodiments, the electrical metric may combine the mean free path and the bulk resistivity in a product λ×ρ₀ quantifying the resistivity associated with scattering from surfaces or grain boundaries of the fourth metal.

Given a choice of electrical metric, the electrical criterion may be determined according to various embodiments. In some embodiments, it may be sufficient for the fourth metal to be as conductive as possible, such that the mean free path may be between 5 and 100 nm; the bulk resistivity may be low (between 1 and 50 μΩ·cm); or λ×ρ₀ may be low (between 10⁻⁶ and 10⁻⁵ μΩ·cm²), respectively. In other embodiments, the electrical criterion may be that a value of the chosen electrical metric for the fourth metal be close to (or even match) a corresponding value for a component of the composite electrode 16, such as the second metal of the second metal electrode 110 or the layer of metal 112.

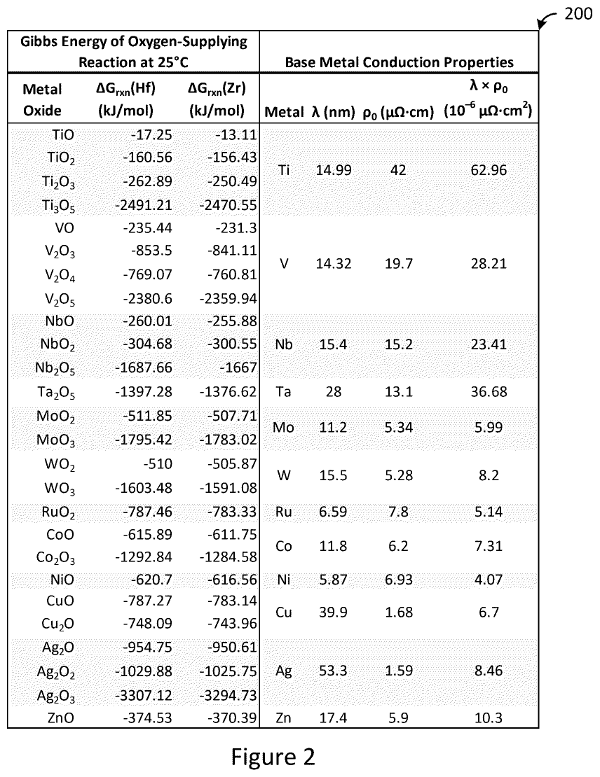

With reference, then, to Equations 3 and 4, and further recalling the possibility that a common stoichiometric factor may be divided out of ΔGᵣₓₙ, FIG. 2 provides a table 200 comprising Gibbs energies of oxygen-supplying reactions at 25° C. for a selection of binary metal oxides with generic chemical formula M^{A}ₖ [symbol] . The oxides tabulated are of transition-metal (d-block) oxides, with the ONs of the metals varying between +2 (e.g., TiO and other compounds with k= [symbol] =1) and +6 (MoO₃). A small number of mixed and non-stoichiometric oxides are also included, such as Ag₂O₂ (one silver atom having an ON of +1 and the other having an ON of +3) and Ti₃O₅.

The table 200 includes Gibbs energies of oxygen-supplying reactions with hafnium and also with zirconium. The Gibbs energies of oxygen-supplying reactions with an average metal atom of HZO may be approximated by a linear interpolation between the respective values, although a modest additional entropic contribution may enter due to the mixing of three elements. (Note also that the non-stoichiometric nature of HZO means that the Gibbs energy need not be explicitly normalized on a per-atom basis.) Because the respective values of the Gibbs energy differ by an average of approximately 1%—except in the outlier case of TiO, which has an unusually small value of ΔGᵣₓₙ—thermodynamic heuristics using either of these values or a linear interpolation may be nearly equivalent. Table 200 further comprises base metal conduction properties for the corresponding fourth metals, with the oxides sorted by fourth metal for convenient reference.

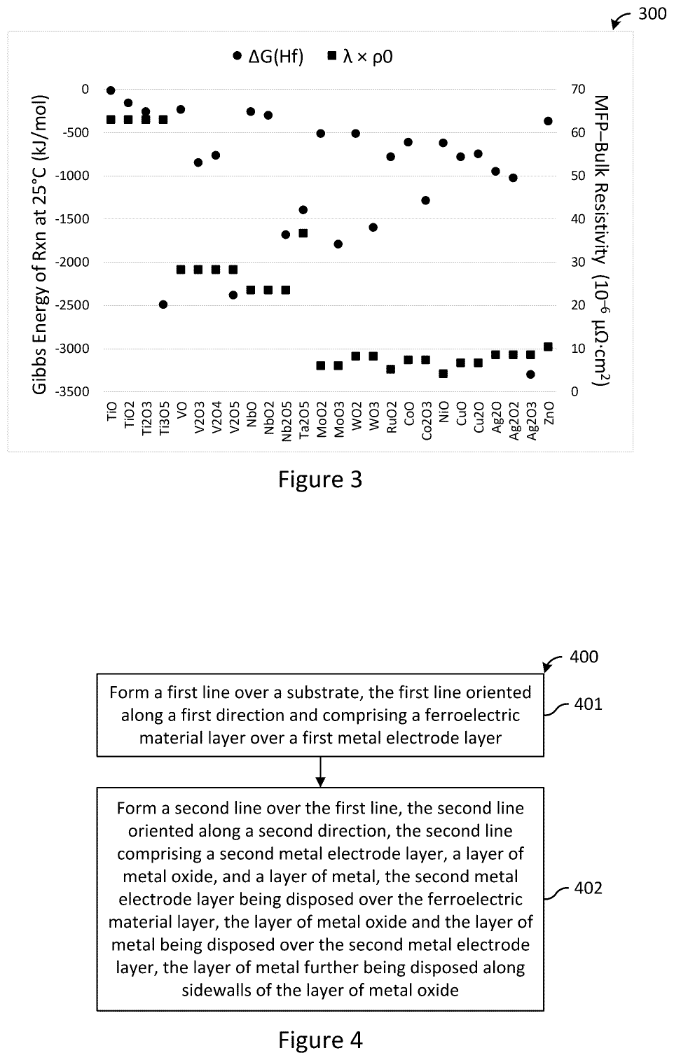

FIG. 3 provides a plot 300 of the Gibbs energies tabulated for oxygen-supplying reactions with hafnium (black circles) and of λ×ρ₀ (black squares). The Gibbs energies are plotted in order of an aufbau progression within the d block, with oxides of all compounds within a group ordered from lowest to highest atomic number and with oxides of a given metal arranged by increasing ON. A weak trend toward more negative Gibbs energy of reaction (a greater propensity to supply oxygen to hafnium) may be present, though a more striking fact is that the highest ON oxides of each element tend to have the most negative values of ΔGᵣₓₙ.

Oxides with a more negative Gibbs energy lie toward the bottom of the plot 300, as do metals with better conductivity. Perusal of the plot 300 thus enables the identification of oxides that may be preferable on the basis of a thermodynamic heuristic (such as that described by Equations 3 and 4), an electrical criterion (such as maximizing the conductivity of any second layer of metal formed from the layer of metal oxide by oxygen transfer), or by balancing these factors in view of design specifications and other practical considerations for a given embodiment.

As indicated in the plot 300, the thermodynamic heuristic based on Equations 3 and 4 may favor metal oxides such as V₂O₅, Ti₃O₅, or Ag₂O₃. By contrast, maximizing the conductivity of the fourth metal of the layer of metal oxide may favor the oxides of electrode materials such as nickel, ruthenium, molybdenum, copper, tungsten, cobalt, silver, and zinc. According to an embodiment in which both thermodynamic heuristic and the electrical criterion are extremized to favor oxygen-supplying reactions and subsequent conduction, the plot 300 suggests that Ag₂O₃ may be an especially attractive choice from the oxides tabulated.

Taken together, the table 200 and the plot 300 are intended to illustrate a sample of candidate oxygen-supplying materials, without excluding other possibilities (such as other oxides or chalcogenides). As long as a thermodynamic heuristic (such as a Gibbs energy calculation for an oxygen-supplying reaction between a given oxide and a ferroelectric of interest) indicates that the material may fill oxygen vacancies in the ferroelectric, and as long as material costs and complexity of integration are not prohibitive, the material may comprise more than one metal; a rare-earth (f-block) metal, a metalloid, or even a nonmetal; a metal with an arbitrarily high positive oxidation state; metal atoms with two or more differing oxidation states; oxygenic anions other than oxide, such as superoxide O²⁻, peroxide O₂²⁻, or ozonide O³⁻; or any other oxygen- or chalcogen-containing compound. Similarly, any material satisfying an electrical criterion (such as minimization of λ×ρ₀ or matching to the second metal electrode 110 or the layer of metal 112) may be used, whether the electrical criterion is used alone or in combination with other factors (such as a thermodynamic heuristic).

Given a choice of metal oxide suitably configured to supply oxygen to a chosen ferroelectric, the metal oxide may be incorporated into a device. Before describing the details of the fabrication process, an embodiment fabrication for forming a ferroelectric device with the metal oxide will be discussed briefly. The process may include the deposition and patterning of the bottom electrode and ferroelectric material layer, e.g., hafnium zirconium oxide (HZO), on a suitable substrate. These steps are followed by the deposition of an interlayer dielectric (ILD) material. A trench is then opened in the ILD using lithography and etching techniques, exposing the top surface of the ferroelectric layer. Next, a layer of electrode metal, e.g., titanium nitride (TiN), is deposited by atomic layer deposition (ALD) to fill the trench. This TiN layer fills a dual role: it serves as a top electrode and provides the necessary conditions for proper crystallization of the HZO layer. An annealing step may then be performed to crystallize the HZO into its desired ferroelectric phase. Following crystallization, the TiN layer may be thinned using an atomic layer etching (ALE) process. This thinning step creates a thin oxygen barrier while maintaining the electrode functionality. The oxygen-supplying layer (or OSL, in some embodiments comprising a layer of metal oxide) is then deposited over the thinned TiN layer, with some embodiments comprising deposition by ALD for thickness control. The OSL is subsequently patterned and etched to align with the underlying ferroelectric capacitor structure, leaving the edges of the top TiN electrode exposed. Finally, an additional metal deposition step may be performed to increase the thickness of the top electrode in areas not covered by the OSL, ensuring good electrical conductivity across the device.

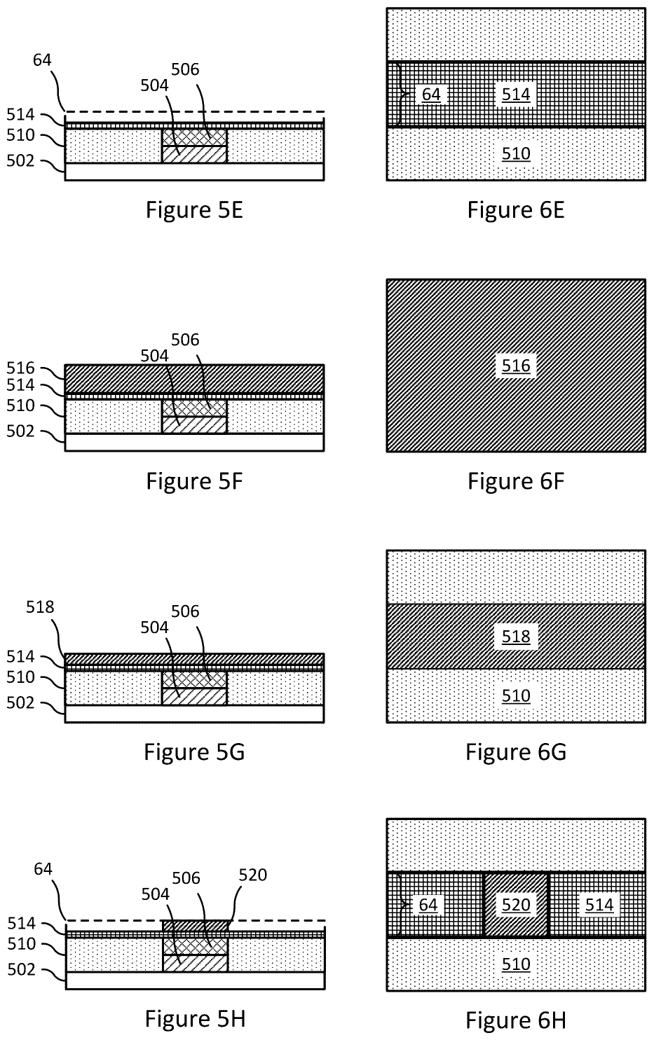

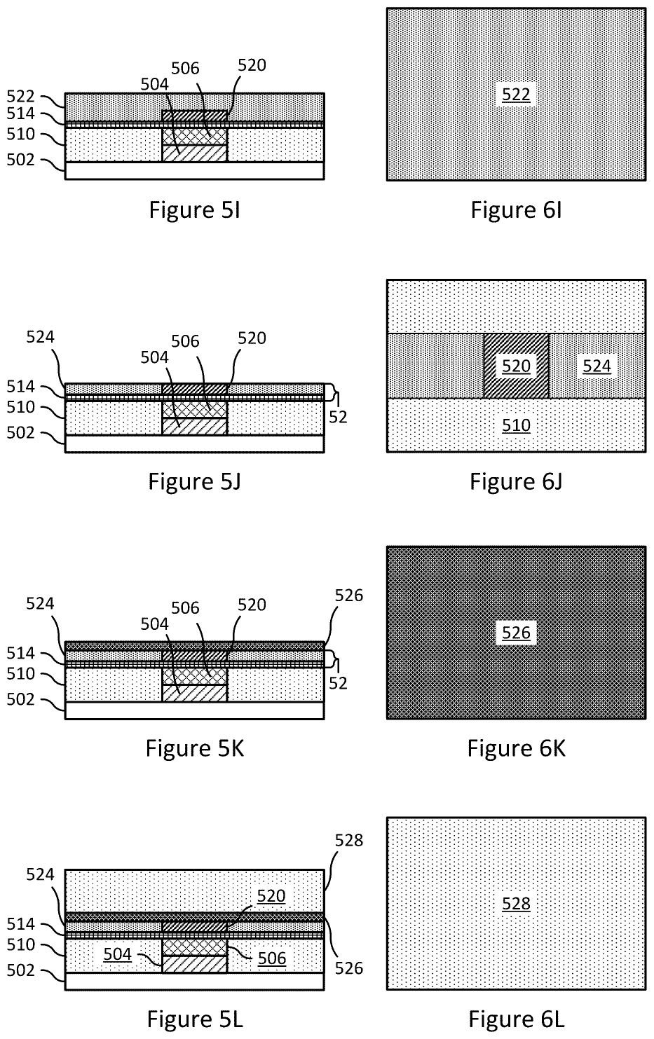

FIGS. 5A-5P and 6A-6P respectively depict cross-sectional and top-down views of the formation of a ferroelectric capacitor followed by formation of a contact via to the ferroelectric capacitor, in accordance with various embodiments. The cross-sectional view in FIG. 5A corresponds to a line 5A-5A′ indicated in FIG. 6A, maintaining consistency with the views presented in FIGS. 1A and 1B. Like reference numerals are used to refer to identical features in the two sets of figures.

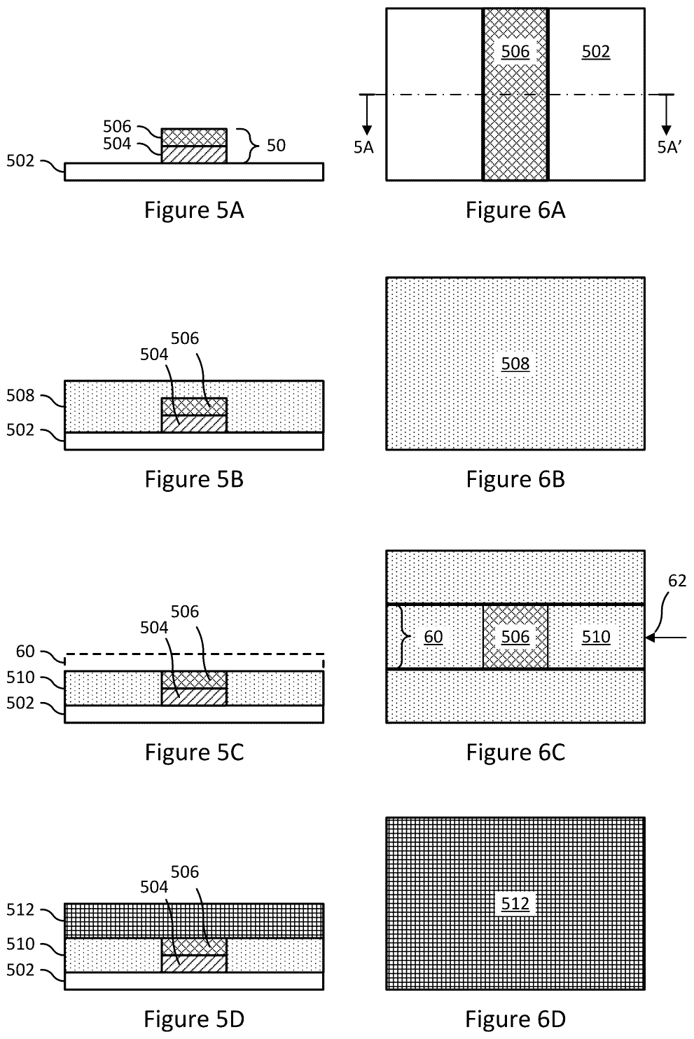

In describing these figures, reference will also be made to FIG. 4, which is a flow chart of a method 400 for forming such devices, according to various embodiments. The method 400 treats the formation of embodiment devices like the electronic device 100 of FIGS. 1A and 1B as having two basic steps, namely, the formation of the first line 12 (box 401) and the formation of the second line 14 (box 402), each line comprising the types and arrangements of components described above with reference to FIGS. 1A/1B (and further described below with reference to FIGS. 7A/7B), in accordance with the various respective embodiments. The relative orientations of the first line 12 and the second line 14 may vary as described previously.

A damascene process of the type illustrated in FIGS. 5B-5J and 6B-6J for forming the second line 14 may be unnecessarily complicated for the fabrication of devices with collinear geometry (relative angle of 0° between the first line 12 and the second line 14). In some such embodiments, device patterning and etching may be performed after the various layers of the electronic device 100 have been deposited according to conventional planar process. Similarly, in some such embodiments, deposition of an interlayer dielectric may be deferred until the corresponding embodiment device is complete. The fact that FIGS. 5A-5J and FIGS. 6A-6J illustrate formation of the electronic device 100 with crosspoint configuration and by a damascene process should not be construed to exclude these possibilities (or indeed any embodiment with non-orthogonal relative angle between the first line 12 and the second line 14).

With reference to FIGS. 5A and 6A, and according to an embodiment, a layer stack may be formed by depositing a first metal electrode (or bottom electrode) 504 over a substrate 502, then depositing a ferroelectric material layer 506 over the bottom electrode 504. The substrate 502, the bottom electrode 504, and the ferroelectric material layer 506 may respectively comprise the materials, structures, devices, and/or other components described above with reference to corresponding parts of FIGS. 1A and 1B.

The bottom electrode 504 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; or any other layer deposition process or combination thereof.

The ferroelectric material layer 506 may be deposited using any suitable deposition technique, such as sol-gel deposition or any of the techniques from the list provided in the previous paragraph. For example, in an ALD process for HZO, alternating pulses of hafnium and zirconium precursors may be introduced into the deposition chamber, typically at temperatures between 200° C. and 400° C. and at low pressures, e.g., between 0.1 and 1 torr. Each precursor pulse may be followed by a purge step to remove excess precursors and byproducts; after the precursor pulses, an oxidant pulse introduces oxygen to oxidize the metal surface, followed by a further purge step to remove organics or other byproducts from the surface. Precursors for hafnium may include hafnium tetrachloride (HfCl₄) or a metal-organic compound like tetrakis(ethylmethylamido)hafnium(IV) (TEMAH); analogous precursors for zirconium may include zirconium tetrachloride (ZrCl₄) or a metal-organic compound like tetrakis(ethylmethylamido)zirconium(IV) (TEMAZ). Water vapor or ozone may be used as the oxidant.

Because each ALD cycle deposits a sub-monolayer of material, the ALD cycle may be repeated until the desired thickness of the HZO film is achieved. The composition of the HZO film may be controlled by adjusting the number, duration, and other parameters of the hafnium and zirconium precursor pulses. The thickness of the resulting ferroelectric material layer 506 may be between 2 nm and 20 nm, according to various embodiments.

Next, the layer stack may be patterned and etched to yield a first line 50 oriented along a first direction parallel to the arrows attached to the line 5A-5A′. (Note that the absolute orientation of the first line 50 may be any direction convenient for the design or fabrication of a device on the given substrate 502.) The patterning and etching may be performed by any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, high-numerical aperture EUV (high-NA EUV), or deep UV (DUV) lithography, in combination with any anisotropic etching method, such as reactive ion etching. The width of the first line 50 (i.e., its critical dimension) may be between 30 nm and 300 nm, according to various embodiments. In one embodiment, the critical dimension of the first line 50 may be between 30 nm and 60 nm.

The first line 50 having been formed consistent with box 401 of method 400, a first interlayer dielectric 508 may be deposited, as depicted in FIGS. 5B and 6B. The first interlayer dielectric 508 may have the composition described previously with reference to FIGS. 1A and 1B and may be deposited using any suitable deposition technique, such as those described above. In an embodiment, the first interlayer dielectric 508 may be silicon oxide deposited by metal-organic CVD using tetraethyl orthosilicate (TEOS).

Next, and with reference to FIGS. 5C and 6C, a first trench 60 may be patterned and etched in the first interlayer dielectric 508 along a second direction 62, yielding a trenched dielectric 510. As illustrated, the second direction 62 is orthogonal to the first direction parallel to the arrows of the line 5A-5A′, eventually yielding a crosspoint geometry for the ferroelectric capacitor; according to a continuum of embodiments, however, any other relative orientation may be chosen. (Again, deposition of the first interlayer dielectric 508 may be deferred and other steps of the process described may be simplified in the event that the chosen geometry is collinear.) The first trench 60 may be sufficiently deep that it reveals an upper surface of the ferroelectric material layer 506.

According to various embodiments, the first trench 60 may be patterned by any suitable lithographic technique described above and any anisotropic etching method, such as reactive ion etching. A resulting width of the first trench 60 may be between 10 nm and 500 nm, and the depth of the first trench 60 may be between 5 nm and 100 nm, according to various embodiments. In some embodiments, the width of the first trench 60 may be chosen to match the critical dimension of the first line 50, such that the first trench 60 exposes a square patch of an upper surface of the ferroelectric material layer 506.

With reference to FIGS. 5D and 6D, a cap layer 512 may next be deposited, filling the first trench 60 to cover the ferroelectric material layer 506 and further covering an upper surface of the trenched dielectric 510. The cap layer 512 may comprise materials described above (with reference to FIGS. 1A and 1B) as appropriate for the second metal electrode 110, and may be deposited by any suitable deposition technique, such as those listed previously.

After the cap layer 512 has been deposited, the ferroelectric material layer 506 may be annealed. The annealing may be performed using a rapid thermal process, furnace annealing, or other suitable annealing method, according to various embodiments. In some embodiments, the annealing method may be a rapid thermal process carried out between 400° C. and 550° C. for 1 s to 60 s, e.g., at 500° C. for 30 seconds. In other embodiments, the annealing method may be annealing in a furnace at 400° C. for 1 hour. Still other embodiments may use annealing methods such as microwave annealing at 2.45 GHz and between 500 W and 3 kW of power for 30 seconds to 5 minutes or RF annealing at 13.56 MHz between 100 W and 1 kW of power for 10 seconds to 2 minutes. Some embodiments may use E-field annealing with a field strength between 1 MV/cm to 10 MV/cm for 5 seconds to 30 seconds, the duration of the annealing being divided among electric field pulses with duration between 1 ms and 100 ms.

Next, the cap layer 512 is etched, removing entirely those portions covering an upper surface of the trenched dielectric 510 and further removing a portion of the material of the cap layer 512 disposed within the first trench 60. The removal of these portions of the cap layer 512 forms a second metal electrode (or top electrode) 514, as depicted in FIGS. 5E and 6E. The thickness of the top electrode 514 may be between 1 nm and 20 nm. An upper surface of the top electrode 514 and any remaining exposed portions of the first trench 60 form a second trench 64.

In some embodiments comprising a cap layer 512 comprising titanium nitride, the etching may be an isotropic atomic layer etch using alternating pulses of ozone (oxidant) and hydrogen fluoride (etchant). Other atomic layer etch chemistries may also be used, comprising oxidants such as oxygen or hydrogen peroxide and etchants such as chlorine or hydrogen chloride, according to various embodiments. In other embodiments, the etching may be a wet etch selective for the cap layer 512 relative to the trenched dielectric 510, such as hot phosphoric acid, in an embodiment. In still other embodiments, etching may be preceded by chemical-mechanical planarization such that the cap layer 512 fills the first trench 60 and has an upper surface flush with an upper surface of the trenched dielectric 510. In certain of these latter embodiments, the trenched dielectric 510 may be protected with a hard mask (such as silicon nitride) and the cap layer 512 subjected to an anisotropic etch (such as reactive ion etching). In some such embodiments, reactive ion etching may be carried out with CClF₃ etchant in O₂ plasma, Cl₂ and/or BCl₃ in Ar plasma, or SF₆ in Ar plasma.

A ferroelectric capacitor having been formed according to the steps just described, an oxygen reservoir may next be formed over the top electrode 514 in order to supply oxygen to the ferroelectric material layer 506. According to some embodiments, a blanket layer of metal oxide 516 may be deposited within the second trench 64 to cover the top electrode 514 and further cover an upper surface of the trenched dielectric 510. The blanket layer of metal oxide 516 may be deposited by any suitable deposition technique, such as those listed above.

The blanket layer of metal oxide 516 may comprise any of the oxides tabulated in table 200, according to various embodiments. In various embodiments, the blanket layer of metal oxide 516 may comprise the fourth metal, and the fourth metal may be a main-group metal or transition metal. In some such embodiments, the blanket layer of metal oxide 516 may comprise a binary compound of the fourth metal and oxygen. In other embodiments, the blanket layer of metal oxide 516 may comprise ternary (M^{(a)}ₓM^{(b)}_{y}O_{z}), quaternary (M^{(a)}ₓM^{(b)}_{y}M^{(c)}_{z}O_{w}), or higher metal oxides of a set of metals {M^{(a)}ₓM^{(b)}_{y}M^{(c)}, . . . } comprising the fourth metal.

In still other embodiments, the blanket layer of metal oxide 516 may comprise a transition metal in the +2 oxidation state, such that the corresponding compound may be an oxide MO, a mixed oxide such as M₃O₄ (not excluding other mixed stoichiometries), a peroxide M(II)O₂, a superoxide M(II)(O₂)₂, or an ozonide M(II)(O₃)₂. In certain embodiments, the blanket layer of metal oxide 516 may comprise a transition metal such as titanium, niobium, molybdenum, tungsten, ruthenium, tantalum, or silver. In particular embodiments, the blanket layer of metal oxide 516 may comprise Ag₂O₃, MoO₃, WO₃, or V₂O₅.

The blanket layer of metal oxide 516 may subsequently be planarized by chemical-mechanical planarization to be flush with an upper surface of the trenched dielectric 510, as illustrated in FIGS. 5G and 6G, yielding a line of metal oxide 518. The line of metal oxide 518 may be patterned and etched to align with the first line 50, such that portions of the top electrode 514 may be revealed and the resulting layer of metal oxide 520 may be disposed over the ferroelectric material layer 506 with the top electrode 514 disposed in between, as depicted in FIGS. 5H and 6H. The patterning and etching methods used may be any suitable methods, such as those described above.

In some embodiments with a width of the first trench 60 (and thus the second trench 64) matching a critical dimension of the first line 50, the layer of metal oxide 520 may comprise a square patch overlying a corresponding square upper surface of the ferroelectric material layer 506. In other embodiments, the layer of metal oxide 520 may comprise a rectangular patch with the width of the first trench 60 (and thus the second trench 64) and with a length matching the critical dimension of the first line 50. In various embodiments, and in order to facilitate oxygen-supplying reactions across an upper cross section of the ferroelectric material layer 506, the layer of metal oxide 520 may be aligned to the ferroelectric material layer 506.

As illustrated in FIGS. 5I and 6I, a blanket layer of metal 522 may next be deposited within the second trench 64 to cover the top electrode 514 and further to cover the layer of metal oxide 520 and an upper surface of the trenched dielectric 510. The blanket layer of metal 522 may comprise any suitable conductive material, such as those described above.

With reference to FIGS. 5J and 6J, the blanket layer of metal 522 may be planarized, such that a resulting layer of metal 524 may be flush with the layer of metal oxide 520 and with an upper surface of the trenched dielectric 510, completing a second line 52 and a corresponding embodiment device. The layer of metal 524 may be non-contiguous and disposed along sidewalls of the layer of metal oxide 520, thus flanking the layer of metal oxide 520.

In certain embodiments, the completed ferroelectric capacitor of FIGS. 5J and 6J may form one component of a linear or planar array in crosspoint configuration. Devices incorporating the completed ferroelectric capacitor of FIGS. 5J and 6J may include, according to various embodiments, FeRAM, FTJs, FeFETs, ferroelectric content-addressable memories (FeCAMs), including ferroelectric ternary CAMs (FeTCAMs), artificial synapses for neuromorphic computing (such as reservoir computing), and other such devices.

The remaining process steps illustrated in FIGS. 5K-5P and 6K-6P comprise formation of a contact via over the ferroelectric capacitor, according to various embodiments. Because the central crosspoint of the device illustrated is occupied by the layer of metal oxide 520 rather than by the layer of metal 524, according to an embodiment, the contact via may be disposed to either side of the layer of metal oxide 520. The contact via will be illustrated as disposed further along the second direction 62 from the layer of metal oxide 520, namely to the left in FIGS. 5M-5P and FIGS. 6M-6P, representing a subset of possible embodiments. The illustrated choice of via placement should not be construed to exclude other possibilities.

As illustrated in FIGS. 5K-5L and 6K-6L, first steps in formation of the contact via may be deposition of an etch stop layer 526 to cover the second line 52, followed by deposition of a second interlayer dielectric 528 to cover the etch stop layer 526. The etch stop layer 526 may comprise any suitable material, such as silicon nitride, and the second interlayer dielectric 528 may comprise any of the interlayer dielectric materials described above. The etch stop layer 526 and the second interlayer dielectric 528 may be deposited using any suitable deposition technique, such as those listed above.

With reference to FIGS. 5M and 6M, a channel 66 may be patterned and etched into the second interlayer dielectric 528 to yield a drilled dielectric 530 and to reveal the etch stop layer 526. The lithographic and etching methods may be as described above, with the etching method being an anisotropic etch.

Next, and with reference to FIGS. 5N and 6N, a wet etch or other isotropic etch selective for the etch stop layer 526 relative to the drilled dielectric 530 may be used to etch a portion of the etch stop layer 526 to form an etched barrier 532 and reveal a portion of an upper surface of the layer of metal 524. The wet etch may comprise any suitable chemistry, including (in an embodiment) hot phosphoric acid. In some embodiments, the wet etch may be a timed etch, such that the etching may be halted just as the channel 66 reaches an upper surface of the layer of metal 524. In these and other embodiments, the wet etch may be selective for the etch stop layer 526 relative to the layer of metal 524 as well as to the drilled dielectric 530.

A contact material 534 may next be deposited to fill the channel 66 and further to cover an upper surface of the drilled dielectric 530, as illustrated in FIGS. 5O and 6O. (The contact material may be any appropriate metallization element, such as any of the electrode materials described above, according to various embodiments.) The contact material 534 may then be planarized to form a contact via 536, as illustrated in FIGS. 5P and 6P.

The electronic device 100 formed by embodiments of the method 400 as illustrated (according to various embodiments) in FIGS. 5A-5J and FIGS. 6A-6J represents one possible device configuration endowing a ferroelectric capacitor with greater durability. Other embodiment configurations may also be advantageous. As an example, FIGS. 7A and 7B depict an electronic device 700, providing cross-sectional and top-down views, respectively. The cross-sectional view in FIG. 7A corresponds to a line 7A-7A′ indicated in FIG. 7B, maintaining consistency with the views presented in FIGS. 1A and 1B and throughout FIGS. 5A-5P and 6A-6P.

The electronic device 700 shares several structural similarities with the electronic device 100 depicted in FIGS. 1A and 1B. Correspondingly labeled structures in both sets of figures may comprise similar materials and may be formed by similar techniques, as detailed in the description of FIGS. 1A and 1B and of FIGS. 5A-5P and 6A-6P.

The primary distinction between electronic device 700 and electronic device 100 lies (with reference to FIGS. 1A and 1B) in the structure of the second line 14 disposed within the trench 18 in the interlayer dielectric 108. In electronic device 700, a second metal electrode (or top electrode) 702 may be deposited to completely fill the trench 18. Subsequently, a channel may be patterned and etched within the second metal electrode 702, exposing a portion of the underlying ferroelectric material layer 106. A layer of metal oxide 704 may then be deposited to fill this channel and subsequently planarized, creating a structure similar to a shallow via. Consequently, the sidewalls of the layer of metal oxide 704 may be continuous and shaped like an ellipse or a circle, rather than the separate rectilinear sidewalls apparent in FIGS. 1A and 1B. In other embodiments, the patterning and etching may form any desirable shape for the sidewalls of the layer of metal oxide 704.

In alternative embodiments, the fabrication sequence may be reversed. The layer of metal oxide 704 may be deposited and patterned first, followed by the deposition and planarization of the second metal electrode 702. In some embodiments with collinear geometry, multiple filled channels like the layer of metal oxide 704 may be disposed at regular intervals along the length of the device.

In embodiments more closely analogous to the electronic device 100, but not as illustrated, the electronic device 700 may still comprise a distinct layer of metal 112 (with reference to FIGS. 1A and 1B) disposed over the second metal electrode 702, with the layer of metal oxide 704 correspondingly filling a channel that extends through the layer of metal 112 and the second metal electrode 702 to make physical contact with the ferroelectric material layer 106. In such embodiments, the layer of metal oxide 704 may therefore still be disposed in part over the second metal electrode 702, with the layer of metal 112 further being disposed along sidewalls of the layer of metal oxide 704.

Irrespective of how the electronic device 700 is fabricated, direct contact between the layer of metal oxide 704 and the ferroelectric material layer 106 may facilitate efficient oxygen transfer between these layers. Without committing to any specific theory, the thicker second metal electrode 702 (and, in some embodiments, additional electrode thickness from the layer of metal 112) may also help to mitigate time-dependence of the electrical properties of electronic device 700 that may arise from the dynamics of oxygen-supplying reactions between the layer of metal oxide 704 and the ferroelectric material layer 106. In particular, a smaller footprint and volume fraction of the layer of metal oxide 704 within the second line 14 may reduce the influence on device properties of microscopic details of the aging or ripening of the layer of metal oxide 704, such as the spatial profile of metallization within the layer of metal oxide 704 as oxygen is supplied to the ferroelectric material layer 106. Any such benefits may be insensitive to whether the second line 14 incorporates a composite electrode (comprising the second metal electrode 702 and the layer of metal 112) or the (unified) second metal electrode 702.

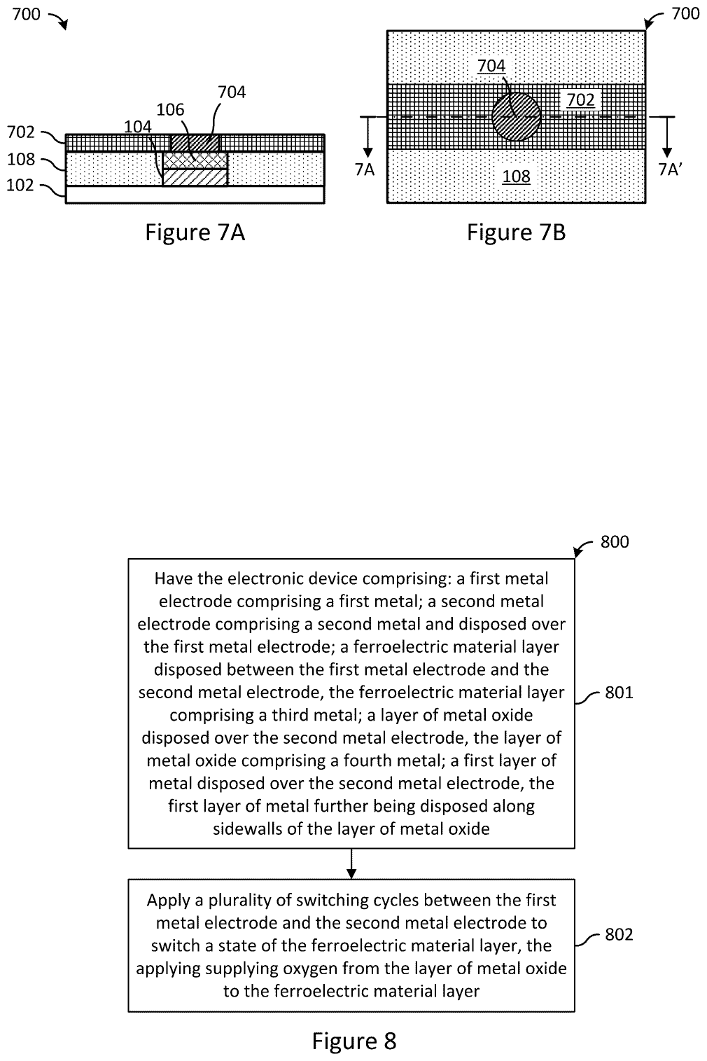

The advantages of the oxygen reservoirs provided by the layer of metal oxide 114 or the layer of metal oxide 704 may be realized by a method 800 illustrated by the flow chart of FIG. 8. A first part (box 801) of the method 800 may be to have the electronic device 100, the electronic device 700, or another embodiment device. Having any such device may result from fabricating it, according to any of the embodiments described, or otherwise obtaining it.

In the absence of an applied voltage, the thermodynamic driving force associated with ΔGᵣₓₙ may cause a limited amount of oxygen to be supplied to the ferroelectric material layer 106 by the layer of metal oxide 114 (through the second metal electrode 110) or the layer of metal oxide 704. Such provision may be modulated by applying a voltage to the device and switching that voltage in order to effect a corresponding change in the polarization state of the device from (say) Pᵣ to −Pᵣ, as may be done (for example) in the course of reading and writing a bit when the device is part of a ferroelectric memory device. While the details of any additional time-varying thermodynamic bias from the switching (as well as the mechanism and kinetics of the oxygen-supplying process) may vary between embodiments and individual devices, the effect may be to stimulate additional supplying of oxygen.

Accordingly, a second part (box 802) of the method 800 is to apply a plurality of switching cycles between the first metal electrode and the second metal electrode to switch a state of the ferroelectric material layer, the applying supplying oxygen from the layer of metal oxide to the ferroelectric material layer. (In some embodiments, the plurality of switching cycles may be a plurality of read-write cycles.) Over the plurality of switching cycles, and as grains of the ferroelectric material layer grow and ripen from the t-phase to the o-phase and then to the m-phase, the layer of metal oxide may provide oxygen to fill vacancies and prevent the formation of leakage paths in the device. The supplying of oxygen may both lengthen the duration of the wake-up period for the device, further forestalling the onset of fatigue, and prevent the formation of leakage paths that may cause device breakdown.

The transfer of oxygen from the layer of metal oxide to the ferroelectric material layer that occurs in the course of the oxygen-supply process may convert a portion of the layer of metal oxide to a second layer of metal comprising the fourth metal. It may be anticipated that the second layer of metal may be adjacent to the second metal electrode 110 in the electronic device 100 or to the ferroelectric material layer 106 in the electronic device 700, according to the respective embodiments. In either case, the second layer of metal may serve as an additional component of the composite electrode 16 within second line 14.

Example embodiments of the invention are described below. Other embodiments can also be understood from the entirety of the specification as well as the claims filed herein.

Example 1. A method of forming an electronic device, the method including: forming a first line over a substrate, the first line oriented along a first direction and including a ferroelectric material layer over a first metal electrode; and forming a second line over the first line, the second line oriented along a second direction, the second line including a second metal electrode, a layer of metal oxide, and a layer of metal, the second metal electrode being disposed over the ferroelectric material layer, the layer of metal oxide and the layer of metal being disposed over the second metal electrode, the layer of metal further being disposed along sidewalls of the layer of metal oxide.

Example 2. The method of example 1, where the second direction is orthogonal to the first direction.

Example 3. The method of one of examples 1 or 2, where forming the first line includes: forming a patterned stack including the first metal electrode and the ferroelectric material layer, the patterned stack being oriented along the first direction.

Example 4. The method of one of examples 1 to 3, where forming the second line includes: forming a trench oriented along the second direction; depositing a cap layer within the trench using a damascene process; annealing the ferroelectric material layer; removing a portion of the cap layer to form the second metal electrode; forming, over the second metal electrode, the layer of metal oxide within the trench, the layer of metal oxide being patterned to align with the first line; and depositing the layer of metal within the trench.

Example 5. The method of one of examples 1 to 4, where the second metal electrode includes a thickness between 1 nm and 20 nm.

Example 6. The method of one of examples 1 to 5, where the layer of metal oxide has a lower affinity for oxygen than the ferroelectric material layer.

Example 7. The method of one of examples 1 to 6, where the metal oxide includes a binary compound of a transition metal and oxygen.

Example 8. The method of one of examples 1 to 7, where the metal oxide includes a transition metal with a +2 oxidation number.

Example 9. The method of one of examples 1 to 8, where the metal oxide includes titanium, niobium, molybdenum, ruthenium, tantalum, tungsten, cobalt, copper, or silver.

Example 10. An electronic device including: a first metal electrode including a first metal; a second metal electrode including a second metal and disposed over the first metal electrode; a ferroelectric material layer disposed between the first metal electrode and the second metal electrode; a layer of metal oxide disposed over the ferroelectric material layer; and a layer of metal disposed over the second metal electrode, the layer of metal further being disposed along sidewalls of the layer of metal oxide.

Example 11. The electronic device of example 10, where the layer of metal oxide is disposed over the second metal electrode.

Example 12. The electronic device of one of examples 10 or 11, where the layer of metal oxide physically contacts the ferroelectric material layer and extends through the layer of metal.

Example 13. The electronic device of one of examples 10 to 12, where the ferroelectric material layer includes a third metal and the layer of metal oxide includes a fourth metal, where the fourth metal includes a lower affinity for oxygen than the third metal.

Example 14. The electronic device of one of examples 10 to 13, further including a contact via disposed over the layer of metal.

Example 15. The electronic device of one of examples 10 to 14, where the metal oxide includes a binary compound of a transition metal and oxygen.

Example 16. The electronic device of one of examples 10 to 15, where the metal oxide includes a transition metal with a +2 oxidation number.

Example 17. The electronic device of one of examples 10 to 16, where the ferroelectric material layer includes a third metal and the layer of metal oxide includes a fourth metal, and where the fourth metal includes titanium, niobium, molybdenum, tungsten, cobalt, copper, ruthenium, tantalum, or silver.

Example 18. The electronic device of one of examples 10 to 17, where the second metal electrode includes titanium nitride, the ferroelectric material layer includes hafnium and zirconium, and the layer of metal oxide includes molybdenum, tungsten, cobalt, copper, or vanadium.

Example 19. The electronic device of one of examples 10 to 18, where the layer of metal includes the second metal.

Example 20. The electronic device of one of examples 10 to 19, where the layer of metal oxide is aligned to the ferroelectric material layer.

Example 21. The electronic device of one of examples 10 to 20, where the sidewalls of the layer of metal oxide are shaped like an ellipse or circle.

Example 22. The electronic device of one of examples 10 to 21, where the electronic device is part of a ferroelectric memory device, a ferroelectric tunnel junction, or a ferroelectric field-effect transistor.

Example 23. A method of operating an electronic device, the method including: having the electronic device including: a first metal electrode including a first metal; a second metal electrode including a second metal and disposed over the first metal electrode; a ferroelectric material layer disposed between the first metal electrode and the second metal electrode, the ferroelectric material layer including a third metal; a layer of metal oxide disposed over the second metal electrode, the layer of metal oxide including a fourth metal; and a first layer of metal disposed over the second metal electrode, the first layer of metal further being disposed along sidewalls of the layer of metal oxide; and applying a plurality of switching cycles between the first metal electrode and the second metal electrode to switch a state of the ferroelectric material layer, the applying supplying oxygen from the layer of metal oxide to the ferroelectric material layer.

Example 24. The method of example 23, where the supplying converts a portion of the layer of metal oxide into a second layer of metal including the fourth metal.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming an electronic device, the method comprising:
forming a first line over a substrate, the first line oriented along a first direction and comprising a ferroelectric material layer over a first metal electrode; and
forming a second line over the first line, the second line oriented along a second direction, the second line comprising a second metal electrode, a layer of metal oxide, and a layer of metal, the second metal electrode being disposed over the ferroelectric material layer, the layer of metal oxide and the layer of metal being disposed over the second metal electrode, the layer of metal further being disposed along sidewalls of the layer of metal oxide.

2. The method of claim 1, wherein the second direction is orthogonal to the first direction.

3. The method of claim 1, wherein forming the first line comprises:
forming a patterned stack comprising the first metal electrode and the ferroelectric material layer, the patterned stack being oriented along the first direction.

4. The method of claim 3, wherein forming the second line comprises:
forming a trench oriented along the second direction;
depositing a cap layer within the trench using a damascene process;
annealing the ferroelectric material layer;
removing a portion of the cap layer to form the second metal electrode;
forming, over the second metal electrode, the layer of metal oxide within the trench, the layer of metal oxide being patterned to align with the first line; and
depositing the layer of metal within the trench.

5. The method of claim 1, wherein the second metal electrode comprises a thickness between 1 nm and 20 nm.

6. The method of claim 1, wherein the layer of metal oxide has a lower affinity for oxygen than the ferroelectric material layer.

7. The method of claim 1, wherein the metal oxide comprises a binary compound of a transition metal and oxygen.

8. The method of claim 1, wherein the metal oxide comprises a transition metal with a +2 oxidation number.

9. The method of claim 1, wherein the metal oxide comprises titanium, niobium, molybdenum, ruthenium, tantalum, tungsten, cobalt, copper, or silver.

10. An electronic device comprising:
a first metal electrode comprising a first metal;
a second metal electrode comprising a second metal and disposed over the first metal electrode;
a ferroelectric material layer disposed between the first metal electrode and the second metal electrode;
a layer of metal oxide disposed over the ferroelectric material layer; and
a layer of metal disposed over the second metal electrode, the layer of metal further being disposed along sidewalls of the layer of metal oxide.

11. The electronic device of claim 10, wherein the layer of metal oxide is disposed over the second metal electrode.

12. The electronic device of claim 10, wherein the layer of metal oxide physically contacts the ferroelectric material layer and extends through the layer of metal.

13. The electronic device of claim 10, wherein the ferroelectric material layer comprises a third metal and the layer of metal oxide comprises a fourth metal, and wherein the fourth metal comprises a lower affinity for oxygen than the third metal.

14. The electronic device of claim 10, further comprising a contact via disposed over the layer of metal.

15. The electronic device of claim 10, wherein the metal oxide comprises a binary compound of a transition metal and oxygen.

16. The electronic device of claim 10, wherein the metal oxide comprises a transition metal with a +2 oxidation number.

17. The electronic device of claim 10, wherein the ferroelectric material layer comprises a third metal and the layer of metal oxide comprises a fourth metal, and wherein the fourth metal comprises titanium, niobium, molybdenum, tungsten, cobalt, copper, ruthenium, tantalum, or silver.

18. The electronic device of claim 10, wherein the second metal electrode comprises titanium nitride, the ferroelectric material layer comprises hafnium and zirconium, and the layer of metal oxide comprises molybdenum, tungsten, cobalt, copper, or vanadium.

19. The electronic device of claim 10, wherein the layer of metal comprises the second metal.

20. The electronic device of claim 10, wherein the electronic device is part of a ferroelectric memory device, a ferroelectric tunnel junction, or a ferroelectric field-effect transistor.

21. A method of operating an electronic device, the method comprising:
having the electronic device comprising:
a first metal electrode comprising a first metal;
a second metal electrode comprising a second metal and disposed over the first metal electrode;
a ferroelectric material layer disposed between the first metal electrode and the second metal electrode, the ferroelectric material layer comprising a third metal;
a layer of metal oxide disposed over the second metal electrode, the layer of metal oxide comprising a fourth metal; and
a first layer of metal disposed over the second metal electrode, the first layer of metal further being disposed along sidewalls of the layer of metal oxide; and
applying a plurality of switching cycles between the first metal electrode and the second metal electrode to switch a state of the ferroelectric material layer, the applying supplying oxygen from the layer of metal oxide to the ferroelectric material layer.

22. The method of claim 21, wherein the supplying converts a portion of the layer of metal oxide into a second layer of metal comprising the fourth metal.
